(19) United States
(12) Patent Application Publication
(10) Pub. No.: US 2012/0045659 A1
(43) Pub. Date: Feb. 23, 2012

(54) PROCESS FOR SURFACE TREATING ALUMINUM OR ALUMINUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); XIAO-QING XIONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/170,919

(22) Filed: Jun. 28, 2011

(30) Foreign Application Priority Data
Aug. 18, 2010 (CN) 201010256595.9

(51) Int. Cl. B32B 15/01; C23C 14/06; C23C 14/35

(52) U.S. Cl. 428/654; 204/192.15

(57) ABSTRACT

An article, includes a substrate made of aluminum or aluminum alloy and a AlON coating formed on the substrate. The AlON coating comprises, between about 50% and about 80% of atomic Al; between about 15% and about 40% of atomic O; and between about 5% and about 10% atomic N.

### CROSS-REFERENCE TO RELATED APPLICATIONS

This application is related to co-pending U.S. Patent Applications (Attorney Docket No. US35134, US36068), each entitled “PROCESS FOR SURFACE TREATING ALUMINUM OR ALUMINUM ALLOY AND ARTICLE MADE WITH SAME”, by Chang et al. These applications have the same assignee as the present application. The above-identified applications are incorporated herein by reference.

### BACKGROUND

1. Technical Field

The disclosure generally relates to processes for surface treating aluminum or aluminum alloy and articles made of aluminum or aluminum alloy treated by the process.

2. Description of Related Art

Due to having many good properties such as light weight and quick heat dissipation, aluminum and aluminum alloy are widely used in manufacturing components (such as housings) of electronic devices. However, aluminum and aluminum alloy have a relatively low erosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for surface treating aluminum or aluminum alloy and articles made of aluminum or aluminum alloy treated by the process. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated by the present process.

FIG. 2 is a schematic view of a magnetron sputtering machine for processing the article in FIG. 1.

FIG. 3 is a field emission stereoscan photograph microscope (50,000× magnified) of an aluminum nitride coating deposited by magnetron sputtering.

FIG. 4 is a field emission stereoscan photograph microscope (50,000× magnified) of an aluminum oxynitride coating formed by an exemplary embodiment of the present process.

FIG. 5 is a field emission stereoscan photograph microscope (100,000× magnified) of the aluminum oxynitride coating in FIG. 4.

### DETAILED DESCRIPTION

An exemplary process for surface treating aluminum or aluminum alloy may include the following steps.

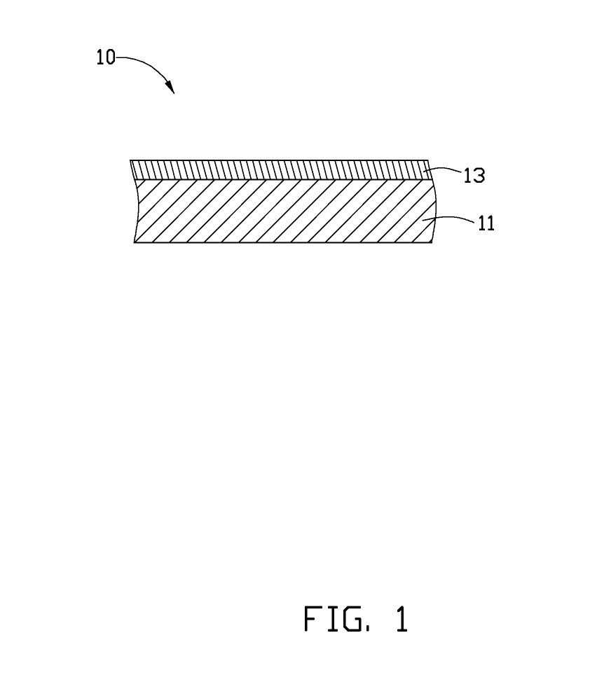

Referring to FIG. 1, a substrate 11 is provided. The substrate 11 is made of aluminum or aluminum alloy.

The substrate 11 is pretreated. For example, the substrate 11 is ultrasonically cleaned with a solution (e.g., alcohol or acetone) in an ultrasonic cleaner, to remove impurities such as grease or dirt from the substrate 11. Then, the substrate 11 is dried.

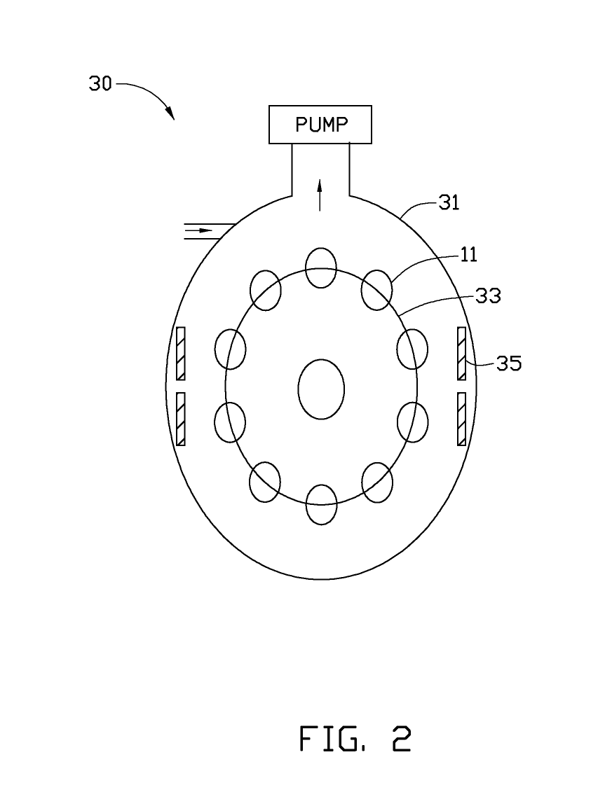

An aluminum oxynitride (AlON) coating 13 is directly formed on the substrate 11 by magnetron sputtering. An exemplary magnetron sputtering process for forming the AlON coating 13 may be performed by the following steps. The substrate 11 is retained on a rotating bracket 33 in a vacuum chamber 31 of a magnetron sputtering machine 30 as shown in FIG. 2. The vacuum chamber 31 is evacuated to maintain a vacuum level in a range from about 5×10⁻³ Pa to about 9×10⁻³ Pa and the inside of chamber 31 is heated to a temperature between about 100° C. and about 180° C. The speed of the rotating bracket 33 is between about 0.5 revolutions per minute (rpm) and about 1 rpm. Argon, oxygen, and nitrogen are simultaneously supplied into the vacuum chamber, with the argon as a sputtering gas, and the oxygen and nitrogen as reactive gases. The flux of the argon is in a range from about 150 Standard Cubic Centimeters per Minute (sccm) to about 300 sccm. The flux of the oxygen is in a range from about 15 sccm to about 70 sccm, and the flux of the nitrogen is in a range from about 10 sccm to about 60 sccm. A bias voltage is applied to the substrate 11 in a range from about −100 volts to about −300 volts. At least one aluminum target 35 is evaporated at a power from about 6 kW and about 12 kW with the duty cycle of between about 40% and about 60% for about 0.5 to about 4 hours, depositing the AlON coating 13 on the substrate 11. The AlON coating 13 has a thickness between about 0.2 μm and about 1.5 μm. The power may be a medium-frequency AC power.

FIG. 1 shows a cross-section of a portion of an exemplary article 10 made of aluminum or aluminum alloy processed by the surface treating as described above. The article may be housings for electronic devices, such as mobile phones. The article 10 includes the substrate 11 made of aluminum or aluminum alloy, the AlON coating 13 directly formed on the substrate 11. In the AlON coating 13, the atomic percentage of Al is about 50% to about 80%; the atomic percentage of O is about 15% to about 40%; the atomic percentage of N is about 5% to about 10%. The AlON coating 13 formed by this exemplary method comprises crystal grains having an average particle diameter in a range from about 6 nm to about 10 nm. Crystal grains having an average particle diameter in a range from about 6 to about 10 nm have smaller spaces between crystal grains than in materials have larger average particle diameters. Thus, the AlON coating 13 has improved density and the article 10 coated with the AlON coating 13 has improved erosion resistance since it becomes harder for contaminants to enter the spaces between the crystal grains.

### EXAMPLES

Experimental examples of the present disclosure are described as follows.

### Example 1

A sample of aluminum alloy substrate was ultrasonically cleaned for about 30 minutes and then was placed into the vacuum chamber 31 of the magnetron sputtering machine 30. The vacuum chamber 31 was evacuated to maintain a vacuum level of about 8×10⁻³ Pa and was heated to a temperature of about 120° C. The speed of the rotating bracket 33 was about 0.5 rpm. Argon, oxygen, and nitrogen were simultaneously fed into the vacuum chamber. The flux of the argon was about 150 sccm. The flux of the oxygen was about 20 sccm, and the flux of the nitrogen was about 15 sccm. The bias voltage applied to the substrate was about −200 volts. The aluminum target was evaporated at a power of about 8 kW with the duty cycle of about 50% for about 1 hour, depositing an AlON coating on the substrate.

### Example 2

Unlike the example 1, in the example 2, the flux of the oxygen was about 40 sccm, and the flux of the nitrogen was about 30 sccm. Except the above difference, the remaining experiment conditions of example 2 were same with example 1. An article of aluminum alloy coated with an AlON coating was obtained according to this example.

The AlON coatings formed in example 1 and 2 have similar microcosmic configuration and surface topography, and have similar erosion resistance.

### Comparison Example

A sample of aluminum alloy substrate was provided. The aluminum alloy substrate was processed by magnetron sputtering in the magnetron sputtering machine 30. Unlike the example 1, just argon and nitrogen were simultaneously fed into the vacuum chamber. The flux of the nitrogen was about 40 sccm. Except the above difference, the remaining experiment conditions of the comparison example were same with example 1. An aluminum nitride (AlN) coating was deposited on the aluminum alloy substrate.

### Results of the Above Examples

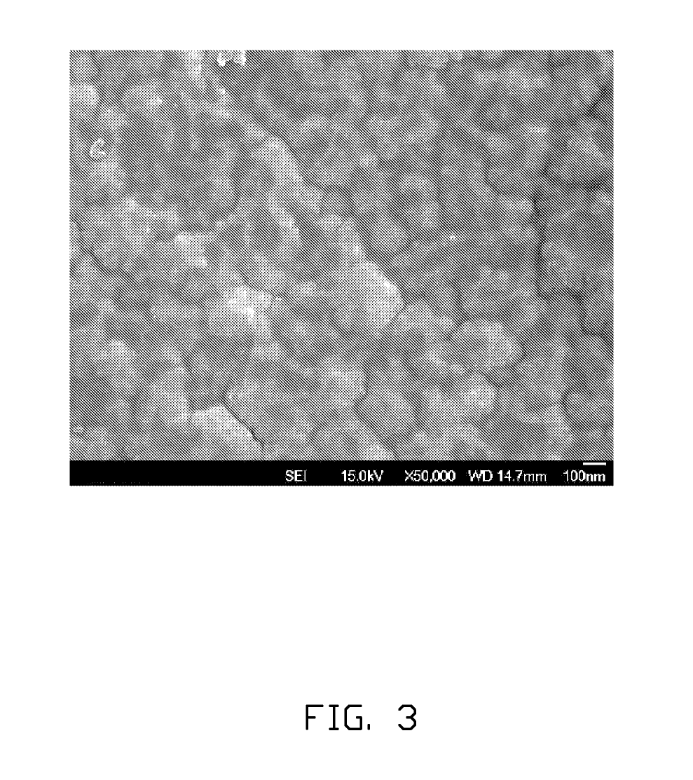

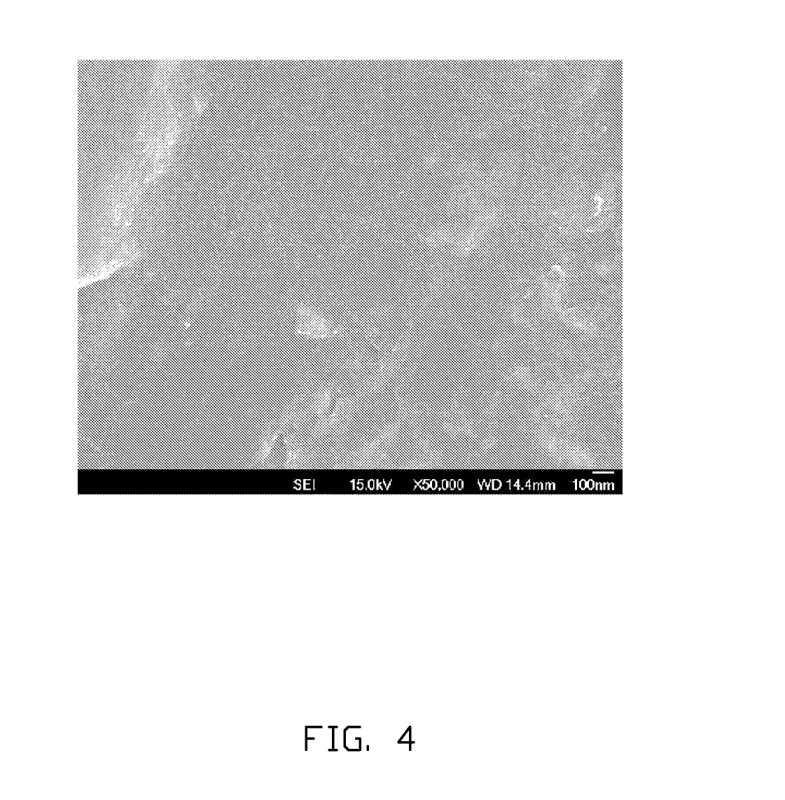

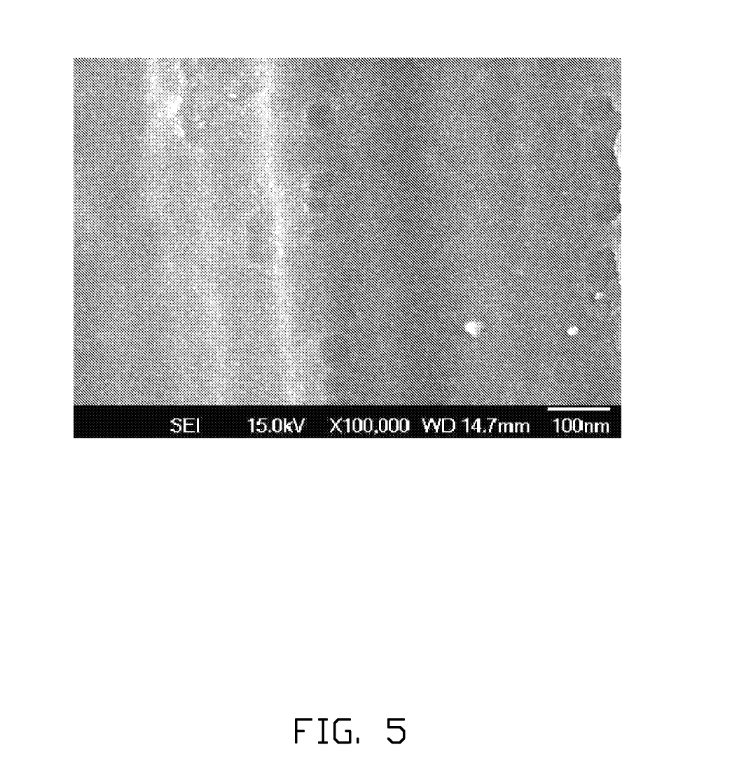

Referring to FIGS. 3 and 4, the AlON coating formed in example 1 and the AlN coating formed in the comparison example were observed by scanning electronic microscopy (SEM). A “JSM-6701F” type field emission scanning electronic microscope sold by JEOL Ltd was used. The scanning indicated that the AlN coating was composed of crystal grains having a larger size than the AlON coating. Accordingly, the AlN coating had larger spaces between the crystal grains as compared to the AlON coating (best shown in FIG. 5). Thus, the AlON coating had an improved density.

A neutral salt spray test was implemented to the samples coated with AlON coatings formed in the examples 1 and 2 and the samples coated AlN coating. The test conditions included 5% NaCl (similar to salt-fog chloride levels), that was neutral at 35° C. to simulate condensing gases with moisture and salt. The test was an accelerated corrosion test for assessing coating performance. Obvious erosion was observed with the sample coated with AlN coating after about 24 hours. However, after about 72 hours, erosion began to be observed with the samples coated with the AlON coatings.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for surface treating aluminum or aluminum alloy, the method comprising the following steps of:
providing a substrate made of aluminum or aluminum alloy; and
forming a AlON coating on the substrate by magnetron sputtering, using aluminum as a target, and nitrogen and oxygen as reactive gases.

2. The method as claimed in claim 1, wherein during magnetron sputtering of the AlON coating, the substrate is retained in a vacuum chamber of a magnetron sputtering machine; the inside of the vacuum chamber is evacuated and heated to a temperature in a range from about 100° C. to about 180° C.; argon, oxygen, and nitrogen are simultaneously floated into the vacuum chamber, the flux of the oxygen is in a range from about 15 to about 70 sccm, and the flux of the nitrogen is in a range from about 10 to about 60 sccm; a bias voltage is applied to the substrate in a range from about −100 volts to about −300 volts; at least one aluminum target is evaporated at a power from about 6 kW and about 12 kW for about 0.5-4 hours.

3. The method as claimed in claim 2, wherein during magnetron sputtering of the AlON coating, the vacuum chamber is evacuated to maintain a vacuum level between about 5×10⁻³ Pa and about 9×10⁻³ Pa; the duty cycle of the power is between about 40% and about 60%; the substrate is retained on a rotating bracket in the vacuum chamber with a rotating speed between about 0.5 rpm and about 1 rpm.

4. The method as claimed in claim 1, wherein the AlON coating comprises, between about 50% and about 80% of atomic Al; between about 15% and about 40% of atomic O; and between about 5% and about 10% of atomic N.

5. The method as claimed in claim 1, wherein the AlON coating comprises crystal grains having an average particle diameter between about 6 nm and about 10 nm.

6. The method as claimed in claim 1, further comprising a step of ultrasonically cleaning the substrate.

7. The method as claimed in claim 1, wherein the AlON coating has a thickness between about 0.2 μm and about 1.5 μm.

8. An article, comprising:
a substrate made of aluminum or aluminum alloy; and
a AlON coating formed on the substrate;
the AlON coating comprises, between about 50% and about 80% of atomic Al; between about 15% and about 40% of atomic O; and between about 5% and about 10% atomic N.

9. The article as claimed in claim 8, wherein the AlON coating comprises crystal grains having an average particle diameter of about 6 nm-10 nm.

10. The article as claimed in claim 8, wherein the AlON coating has a thickness between about 0.2 μm and about 1.5 μm.

11. The article as claimed in claim 8, wherein the AlON coating is deposited by magnetron sputtering.

12. The article as claimed in claim 8, wherein the article is a housing of electronic devices.
